(19) United States
(12) Patent Application Publication
(10) Pub. No.: US 2007/0145010 A1
(43) Pub. Date: Jun. 28, 2007

(54) Removal rate estimating method of a chemical mechanical polishing process under mixed products or mixed layers

(75) Inventors: Ming-Wei Lee, Taipei (TW); Chih-Wei Lai, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/512,194

(22) Filed: Aug. 30, 2006

(30) Foreign Application Priority Data
Dec. 23, 2005 (TW) 94146093

(51) Int. Cl. C03C 15/00; H01L 21/461; B44C 1/22; H01L 21/302

(52) U.S. Cl. 216/84; 438/692; 216/88

(57) ABSTRACT

A removal rate estimating method of a chemical mechanical polishing process under mixed products or mixed layers is provided, the estimation at least comprises: providing a pad removal rate of a specific product or layer; providing a removal rate adjustment; and summing up the pad removal rate of the specific product or layer and the removal rate adjustment as an estimated value of the removal rate of the chemical mechanical polishing process under mixed products or mixed layers. Wherein the value of the removal rate adjustment will be set to zero when the pad is replaced with a new one.

### BACKGROUND OF THE INVENTION

1. Field of the Invention

The present invention relates to a removal rate estimating method of a chemical mechanical polishing process under mixed products or mixed layers, especially to summing up the pad removal rate and the removal rate adjustment as an estimated value of the removal rate of the chemical mechanical polishing process under mixed products or mixed layers.

2. Description of the Related Art

The vigorous developments in optoelectric and semiconductor industries have brought much progress in other related hi-tech industries. Optoelectric and semiconductor industries require advanced technology and the costs for building a factory, operation and research are very high, also own the highest level of automation. Generally, the optoelectric and semiconductor processes are very complex and several hundreds of different steps and 1-2 months are needed, such that the cost is also very huge. Additionally, any instability in one process control will often influence subsequent processes and therefore result in unrecoverable losses. Accordingly, with the intense competition in the optoelectric and semiconductor markets, the process operation and monitor and the product quality control are becoming increasingly important. Especially, when similar technologies are used, increasing the product quality in order to efficiently increase the product yield rate will become a key factor to the product competitiveness.

In addition to the design prior to the production and the verification posterior to the production, a stable process is further needed in order to efficiently increase the product yield rate. Generally, the result of a process will often deviate from the predetermined target due to the wear of the mechanical apparatus, the consumption of the material, periodical maintenances or replacing a new process, resulting the variation in the process quality and thereby decreasing the product yield rate. For efficiently eliminating the deviation of the result of a process from the predetermined target, many run-to-run algorithms have been provided, such that process parameters or machine parameters can be adjusted based on the established mode, in order to eliminate process variations.

Chemical mechanical polishing (CMP) is an important semiconductor process with a simple mechanism. However, this process mainly uses consumptive material and great variations are generated in this process. The CMP process is performed by adding slurry between a wafer and a pad and moving the wafer face to be planarized, in order to rub the wafer face. Particles in the slurry will destroy the mechanical properties of the wafer surface, decrease the material strength and result in more chemical damages, or the surface will be broken into fragments and dissolved in and brought away by the slurry. Because most chemical reactions are isotropic, the CMP apparatus must be specially designed in order to provide high removal rate for polishing projecting points and achieve the purpose of planarization.

The controlled parameters for a CMP machine generally comprise rotating speed, sucker pressure, force on the pad, and slurry concentration, which controlled parameters have been described in many patents and the description thereof is not duplicated. If a single product is considered, the same parameters will be used and therefore the variations in the above parameters can be omitted. Nevertheless, other parameters are still needed to be considered, such as the model number of the pad, the life time of the pad, and the polishing time which is the major operative variable.

Currently, the CMP process division in some wafer factories even manually adjusts critical operative parameters by the operator on the spot lot to lot or wafer to wafer, meaning that traditionally the estimated value of the removal rate is an empirical value due to the unidentifiable variances (drift and disturbance) in the process. Therefore, as to the current CMP process technology, a removal rate estimating method for the planarization of several products or different layers is still needed.

### SUMMARY OF THE INVENTION

The present invention establishes a removal rate estimating method for the process variation applicable to a process with several kinds of products on a line or the planarization of different layers, such that the polishing time of the process can be estimated, in order to solve the problems such as the unidentifiable variances (drift and disturbance) in the process, the consideration of the model number of the pad, the life time of the pad, etc. In this manner, it will help the manufacturer automatize this operative step and adjust the machine parameters in order to maintain the process quality above the target value and increase the product quality stability and final product yield rate.

To achieve the above object, the removal rate estimating method of a chemical mechanical polishing process under mixed products or mixed layers of the present invention provides an estimated value for estimating the removal rate influenced by an aged pad, comprising: providing a pad removal rate of a specific product or layer; providing a removal rate adjustment calculated by an adaptive algorithm; and summing up the pad removal rate of the specific product or layer and the removal rate adjustment as an estimated value of the removal rate of the chemical mechanical polishing process under mixed products or mixed layers. When the estimated value of the removal rate is computed, a polished thickness target can be subtracted from the thickness prior to polishing, and then the resulting value can be divided by the estimated value of the removal rate, such that the polishing time required for the next lot or wafer can be estimated. When the pad is replaced with a new one, the value of the removal rate adjustment will be set to zero and continually substituted into the above computing process, such that the required polishing time still can be obtained. The present invention, i.e. the novel removal rate estimating method of a chemical mechanical polishing process, is more precise than traditional estimating methods under mixed products or mixed layers and can also be applied under identical layer and identical product.

It is another object of the present invention to divide the estimated value of the removal rate of the chemical mechanical polishing process under mixed products or mixed layers into a pad removal rate of a specific product or layer and a removal rate adjustment, and the divided removal rate adjustment can be computed from various mathematically adaptive algorithms, in order to estimate the estimated value of the removal rate for next process. Preferably, the above mathematically adaptive algorithms comprise the algorithms such as EWMA, Double-EWMA, Age-Based Double EWMA, etc. The estimated value of the removal rate obtained by various mathematically adaptive algorithms is more precise than traditional estimating methods by at least 25%.

### BRIEF DESCRIPTION OF THE DRAWINGS

FIG. 1 is a flow chart of the removal rate estimating method of a chemical mechanical polishing process under mixed products or mixed layers of the present invention.

FIG. 2 is a comparison between the EWMA estimation of the removal rate estimating method of a chemical mechanical polishing process under mixed products or mixed layers of the present invention and a traditional estimation.

### DETAILED DESCRIPTION OF THE PREFERRED EMBODIMENTS

The removal rate estimating method of a chemical mechanical polishing process under mixed products or mixed layers of the present invention comprises: providing a pad removal rate of a specific product or layer; providing a removal rate adjustment; and summing up the pad removal rate of the specific product or layer and the removal rate adjustment as an estimated value of the removal rate of the chemical mechanical polishing process under mixed products or mixed layers. And the removal rate adjustment can be computed from various mathematically adaptive algorithms, in order to estimate the estimated value of the removal rate for the next lot or wafer. The removal rate estimating method of a chemical mechanical polishing process under mixed products or mixed layers of the present invention will be described in detail by the following embodiments in conjunction with accompanying figures.

During a chemical mechanical polishing process, an aged pad will influence the removal rate and therefore make the polished thickness deviate from the predetermined target, such that variances will be generated in the process quality. Considering the factor of aged pads, the estimated value of the removal rate can be estimated by a pad removal rate of a specific product or layer and a removal rate adjustment for the removal rate deviation due to the aged pad, the relationship is given as follows:

the estimated removal rate of a chemical mechanical polishing process under mixed products or mixed layers (\hat{R})=the pad removal rate of a specific product or layer (R_{org})+the removal rate adjustment (\hat{R}_{adj}) wherein the pad removal rate of a specific product or layer( R_{org}) is an original property parameter for a machine or product depending on different products or layers before a pad is aged, and the removal rate adjustment (\hat{R}_{adj}) is a correction for the removal rate deviation due to the aged pad.

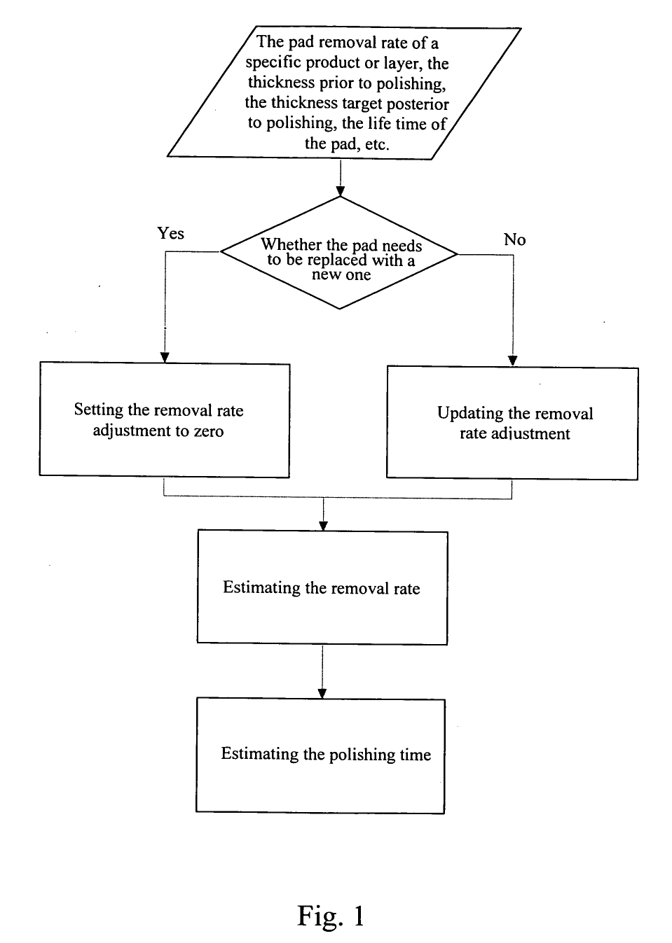

Referring to FIG. 1, a flow chart of the removal rate estimating method of a chemical mechanical polishing process under mixed products or mixed layers of the present invention is shown. First of all, the information such as the pad removal rate of a specific product or layer, the thickness prior to polishing, the thickness target posterior to polishing, the life time of the pad, etc. is obtained. Then it is determined whether the pad needs to be replaced with a new one before the polishing. If no, the removal rate adjustment is updated; whereas if yes, the pad will then be replaced with a new one, and the removal rate adjustment is set to zero in order to estimate the removal rate (\hat{R}). When the estimated value of the removal rate is computed, a polished thickness target can be subtracted from the thickness prior to polishing, and then the resulting value can be divided by the estimated value of the removal rate, such that the polishing time required by the next lot or wafer can be estimated. The resulting required polishing time could be used to adjust the machine parameters in order to maintain the process quality at the target value and increase the product quality stability and yield rate.

Subsequently, to obtain the estimated removal rate (\hat{R})ᵢ₊₁, for the next lot or wafer, the above relationship could be equivalently applied as follows:

(\hat{R})ᵢ₊₁=(R_{org})ᵢ₊₁+(\hat{R}_{adj})ᵢ₊₁

wherein (\hat{R}_{adj})ᵢ₊₁ can be obtained by various mathematically adaptive algorithms typically such as EWMA, Double-EWMA, Age-Based Double EWMA, etc. As an example of EWMA algorithm, the estimation is performed as follows:

(\hat{R}_{adj})ᵢ₊₁=w(\hat{R}_{adj})ᵢ+(1−w)(\hat{R}_{adj})ᵢ

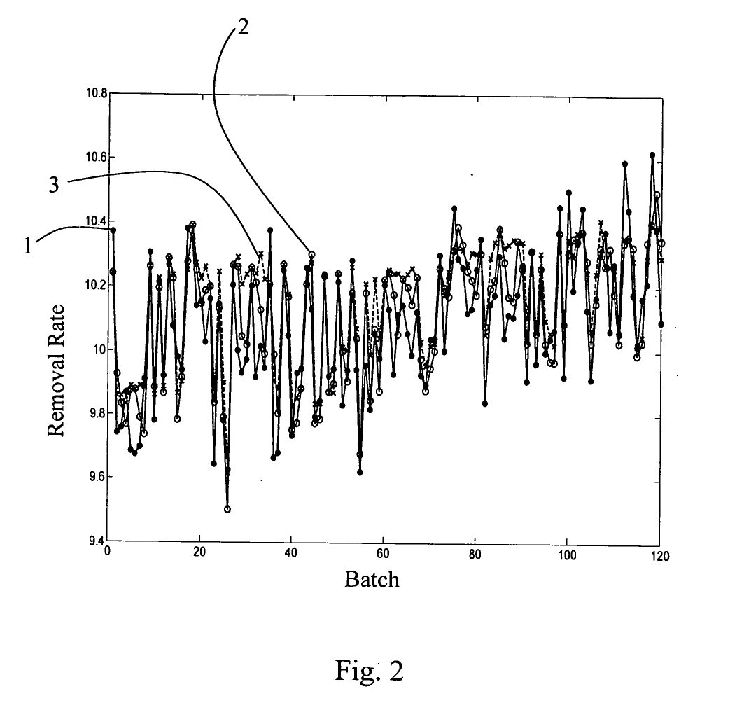

(\hat{R})ᵢ₊₁=(R_{org})ᵢ₊₁+(\hat{R}_{adj})ᵢ₊₁

wherein w is the tuning parameter for the EWMA. When the pad is replaced with a new one, i=1, then (\hat{R}_{adj})₁=0, such that the estimated removal rate (\hat{R})ᵢ₊₁ can be calculated After that, a polished thickness target can be subtracted from the thickness prior to polishing, and then the resulting value can be divided by the estimated value of the removal rate (\hat{R})ᵢ₊₁, such that the polishing time required for the next lot or wafer can be estimated. The resulting required polishing time could be used to adjust the machine parameters in order to maintain the process quality at the target value and increase the product quality stability and yield rate. A comparison between the EWMA estimation of the removal rate estimating method of a chemical mechanical polishing process under mixed products or mixed layers of the present invention and a traditional EWMA estimation is shown in FIG. 2. From the figure, it is apparent that the difference between the estimated value of the removal rate obtained by present invention (2) and the real removal rate (1) is more precise than the difference between the traditional estimating method (3) and the real removal rate (1) by at least 25%.

The present invention, i.e. the novel removal rate estimating method of a chemical mechanical polishing process under mixed products or mixed layers, can also be applied under identical layer and identical product.

It is to be understood that the foregoing general description is exemplary and explanatory only and is not restrictive of the invention as claimed. Various equivalent alterations and modifications can be made without departing from the spirit of the present invention and are within the scope of the following claims.

What is claimed is:

1. A removal rate estimating method of a chemical mechanical polishing process, comprising:
providing a pad removal rate of a specific product or layer;
providing a removal rate adjustment; and
summing up said pad removal rate of the specific product or layer and said removal rate adjustment as an estimated value of the removal rate of the chemical mechanical polishing process.

2. The removal rate estimating method of a chemical mechanical polishing process as claimed in claim 1, wherein said removal rate adjustment of the chemical mechanical polishing process is used to estimate next removal rate adjustment by an adaptive algorithm, such that an estimated value of the removal rate of the next lot or wafer to be processed in the chemical mechanical polishing equipment can be estimated.

3. A removal rate estimating method of a chemical mechanical polishing process under mixed products or mixed layers, comprising:
providing a pad removal rate of a specific product or layer;
providing a removal rate adjustment;
summing up said pad removal rate of the specific product or layer and said removal rate adjustment as an estimated value of the removal rate of the chemical mechanical polishing process under mixed products or mixed layers; and
said removal rate adjustment will be set to zero when the pad is replaced with a new one.

4. The removal rate estimating method of a chemical mechanical polishing process under mixed products or mixed layers as claimed in claim 3, wherein said removal rate adjustment of the chemical mechanical polishing process is used to estimate next removal rate adjustment by an adaptive algorithm, such that an estimated value of the removal rate of the next lot or wafer to be processed in the chemical mechanical polishing equipment can be estimated.

5. The removal rate estimating method of a chemical mechanical polishing process as claimed in claim 2, wherein said adaptive algorithm is a mathematically adaptive algorithm.

6. The removal rate estimating method of a chemical mechanical polishing process under mixed products or mixed layers as claimed in claim 4, wherein said adaptive algorithm is a mathematically adaptive algorithm.

7. The removal rate estimating method of a chemical mechanical polishing process as claimed in claim 5, wherein said adaptive algorithm is one of the following algorithms: EWMA, Double-EWMA, Age-Based Double EWMA.

8. The removal rate estimating method of a chemical mechanical polishing process under mixed products or mixed layers as claimed in claim 6, wherein said adaptive algorithm is one of the following algorithms: EWMA, Double-EWMA, Age-Based Double EWMA.
